(19) United States
(12) Patent Application Publication
(10) Pub. No.: US 2026/0089903 A1
(43) Pub. Date: Mar. 26, 2026

(54) THERMAL AND EMI SHIELDING FOR PERIPHERAL DEVICES

(71) Applicant: Intel Corporation, Santa Clara, CA (US)

(72) Inventors: Ezekiel Poulose, Kochi (IN); Avinash Manu Aravindan, Pallickal (IN); Prakash Kurma Raju, Bangalore (IN); Amarjeet Kumar, Bangalore (IN); Tejasweeni D. Lingayat, Ratnagiri (IN); Prasanna Pichumani, Bangalore (IN); Nehakausar A. Mansuri, Bangalore (IN); Arumanayagam Rajasekar, Nagercoil (IN); Bala Subramanya, Bangalore (IN); Jayprakash Thakur, Bangalore (IN)

(73) Assignee: Intel Corporation, Santa Clara, CA (US)

(21) Appl. No.: 19/304,165

(22) Filed: Aug. 19, 2025

Related U.S. Application Data
(63) Continuation of application No. PCT/US2024/048213, filed on Sep. 24, 2024.

(51) Int. Cl. H05K 9/00; H05K 7/20

(52) U.S. Cl. CPC H05K 9/0037; H05K 7/2039

(57) ABSTRACT

In one embodiment, a housing is coupled to a device connector (e.g., an M.2-compatible expansion slot) on a circuit board. The housing may be a conductive material (e.g., metal) and sized to cover a device coupled to the connector such that the device may be substantially encompassed by the housing and the circuit board. The housing may contact, directly or indirectly, the device to provide thermal transfer. In addition, the housing may be connected to ground to provide electromagnetic interference (EMI) shielding of the device.

### CROSS-REFERENCE TO RELATED APPLICATION(S)

This application is a continuation of International Application No. PCT/US2024/048213, filed Sep. 24, 2024, entitled “THERMAL AND EMI SHIELDING FOR PERIPHERAL DEVICES,” the entirety of which application is incorporated herein by reference in its entirety.

### BACKGROUND

Next-generation solid state drive (SSD) technologies may require power in the range of 6 W-8 W, which might prove to be a challenge. For example, thermal handling may be difficult due to the relatively small volumetric space available in such drives, and thermal throttling may cause reduced data throughputs and disruptions to the user experience. Moreover, electromagnetic interference (EMI) may also be challenging given the higher frequencies used in the drives.

### BRIEF DESCRIPTION OF THE DRAWINGS

FIGS. 1A-1C illustrate perspective views of an example system incorporating a thermal/EMI shielding cover of the present disclosure.

FIG. 2 illustrates a side view of the example system of FIGS. 1A-1C.

FIG. 3 illustrates an example mechanism for coupling a thermal/EMI shielding cover to a device connector.

FIGS. 4A-4B illustrate another example mechanism for coupling a thermal/EMI shielding cover to a device connector.

FIGS. 5A-5B illustrate an example mechanism for coupling a thermal/EMI shielding cover to a circuit board.

FIGS. 6A-6B illustrate another example mechanism for coupling a thermal/EMI shielding cover to a circuit board.

FIG. 7 illustrates an example computing device in which aspects of the present disclosure may be incorporated.

FIG. 8 illustrates a simplified block diagram of a computing device in which aspects of the present disclosure may be incorporated.

FIG. 9 is a block diagram of computing device components which may be included in a mobile computing device incorporating aspects of the present disclosure.

### DETAILED DESCRIPTION

In the following description, specific details are set forth, but aspects of the technologies described herein may be practiced without these specific details. Well-known circuits, structures, and techniques have not been shown in detail to avoid obscuring an understanding of this description. “An embodiment,” “various embodiments,” “some embodiments,” and the like may include features, structures, or characteristics, but not every embodiment necessarily includes the particular features, structures, or characteristics.

Some embodiments may have some, all, or none of the features described for other embodiments. “First,” “second,” “third,” and the like describe a common object and indicate different instances of like objects being referred to. Such adjectives do not imply objects so described must be in a given sequence, either temporally or spatially, in ranking, or any other manner. “Connected” may indicate elements are in direct physical or electrical contact with each other and “coupled” may indicate elements co-operate or interact with each other, but they may or may not be in direct physical or electrical contact. Terms modified by the word “substantially” include arrangements, orientations, spacings, or positions that vary slightly from the meaning of the unmodified term. For example, description of a lid of a mobile computing device that can rotate to substantially 360 degrees with respect to a base of the mobile computing includes lids that can rotate to within several degrees of 360 degrees with respect to a device base.

The description may use the phrases “in an embodiment,” “in embodiments,” “in some embodiments,” and/or “in various embodiments,” each of which may refer to one or more of the same or different embodiments. Furthermore, the terms “comprising,” “including,” “having,” and the like, as used with respect to aspects of the present disclosure, are synonymous.

Reference is now made to the drawings, which are not necessarily drawn to scale, wherein similar or same numbers may be used to designate same or similar parts in different figures. The use of similar or same numbers in different figures does not mean all figures including similar or same numbers constitute a single or same embodiment. Like numerals having different letter suffixes may represent different instances of similar components. The drawings illustrate generally, by way of example, but not by way of limitation, various embodiments discussed in the present document.

In the following description, for purposes of explanation, numerous specific details are set forth in order to provide a thorough understanding thereof. It may be evident, however, that the novel embodiments can be practiced without these specific details. In other instances, well known structures and devices are shown in block diagram form in order to facilitate a description thereof. The intention is to cover all modifications, equivalents, and alternatives within the scope of the claims. While aspects of the present disclosure may be used in any suitable type of computing device, the examples below describe example mobile computing devices/environments in which aspects of the present disclosure can be implemented.

### Novel Thermal and EMI Shielding for Peripheral Devices

Aspects of the present disclosure include novel thermal and EMI shielding for peripheral devices, e.g., M.2-compatible solid state drives (SSDs), wireless communications devices (e.g., wireless local area network (WLAN)/wireless wide area network (WWAN) antennas), or similar. Current techniques for thermal handling in these devices may include a heatsink that adds considerable Z-stack impact (especially in laptop devices), or throttling the device performance that negatively affects user experience. There are some options for attaching copper plate heat spreaders, but these require additional assembly/disassembly steps in addition to the attach/detach process for the device itself, impacting the costs and/or time needed for repairs. Another current solution involves Graphene sheet wrapping of the device, which can address both EMI and thermal issues; however, while functional, this solution provides a negative user experience from both an aesthetics and repairability standpoint.

Aspects of the present disclosure, by contrast, provide heat spreading and EMI shielding for M.2-compatible or similar peripheral devices while also providing limited impact on assembly/disassembly and repairability. Particular embodiments may include a cover attached to an M.2-compatible (or similar) connector, socket, or expansion slot of a printed circuit board (PCB), e.g., via a hinge mechanism on an M.2-compatible connector. The cover may function as a heat spreader that is sufficient to avoid thermal hotspots on the device that would otherwise cause thermal throttling in the device without requiring a heat sink to be attached in current techniques and without requiring the same z-height impact. The cover can also function as an EMI shield, with a proper ground contact between the cover and a ground connection in the main circuit board the device is connected to. In certain embodiments, an M.2-compatible (or similar) connector can be provisioned to attach the cover with a simple hinge mechanism. Further, certain embodiments may implement thermal gap pads coupled to chips of the device such that the gap pads provide a thermal connection between the device and the cover.

Embodiments herein can provide one or more advantages over existing thermal/EMI solutions. For example, some embodiments, can ensure that thermal and EMI performance requirements for next generation M.2-compatible (or similar) devices can be achieved without impacting repairability. For instance, some embodiments can provide a simple hinged solution for attachment of the cover to the device-to-circuit board connector, which can allow for a platform-based solution as compared with current module-based solutions (e.g., heatsinks). This can also allow for such attachments to be standardized via particular specifications, similar to the M.2 or other peripheral device specifications. Furthermore, aspects of the present disclosure allow an easily scalable solution that can be used for a variety of form factors, such as, for example, 2280, 2242, or 2230 SSDs, or WLAN/WWAN antenna modules. As used herein, “M.2-compatible” may refer to a device (e.g., an expansion card) or device connector (e.g., an expansion slot) that is compatible with specifications promulgated by the PCI-SIG or SATA-IO related to the M.2 form factor and/or aspects related to the functioning of such devices, e.g., the PCI Express M.2 Specification (any revision) or Serial ATA specifications related to M.2. Although M.2 devices and connectors are described herein, aspects of the preset disclosure may be adapted for other types of peripheral or add-on devices and connectors, including those that may succeed the M.2 standards.

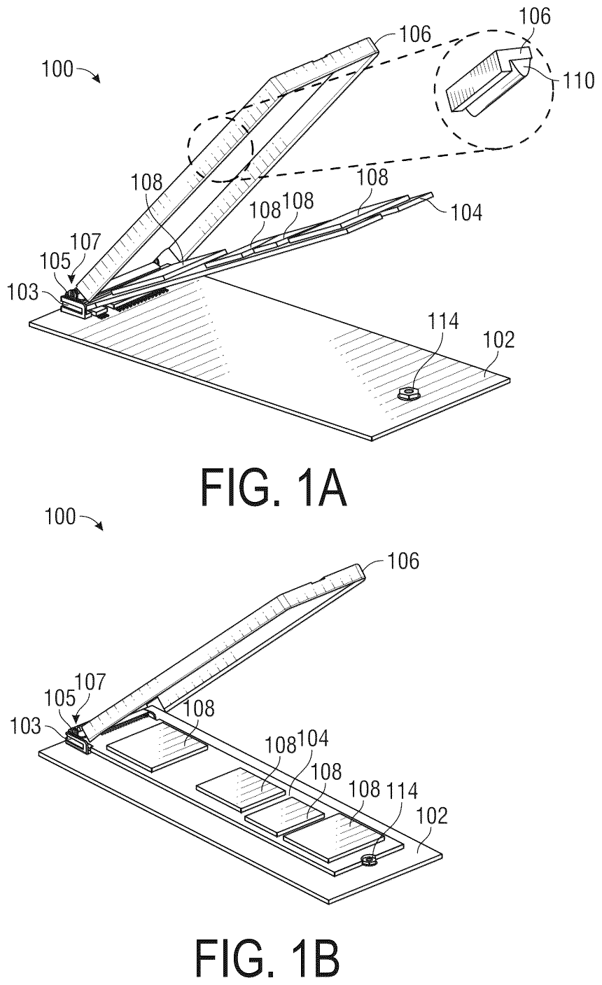

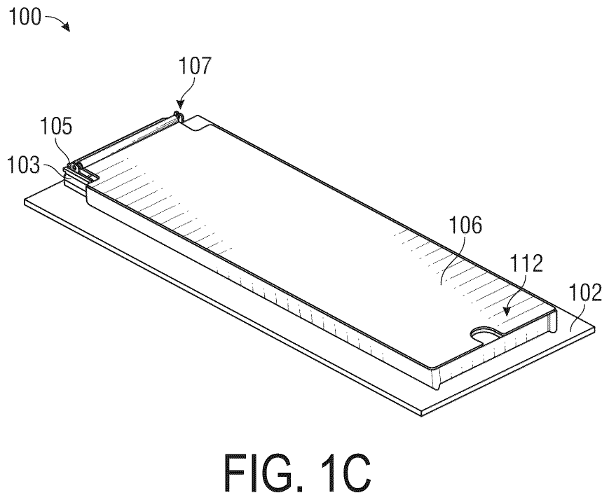

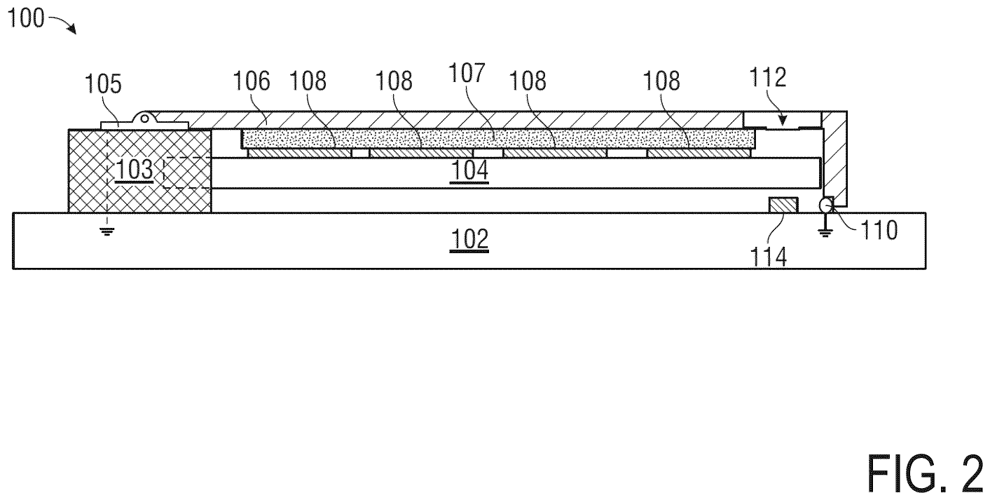

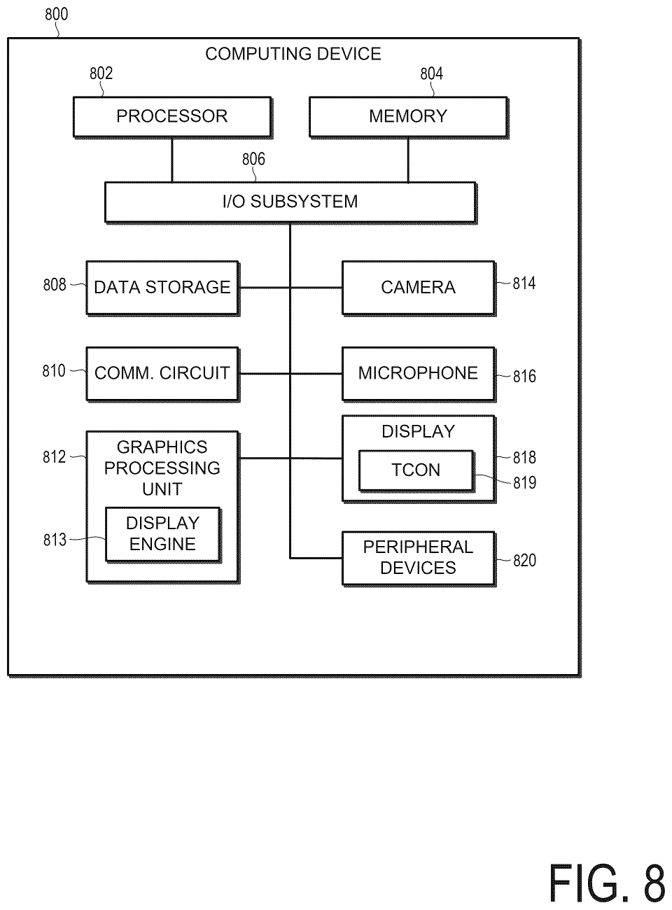

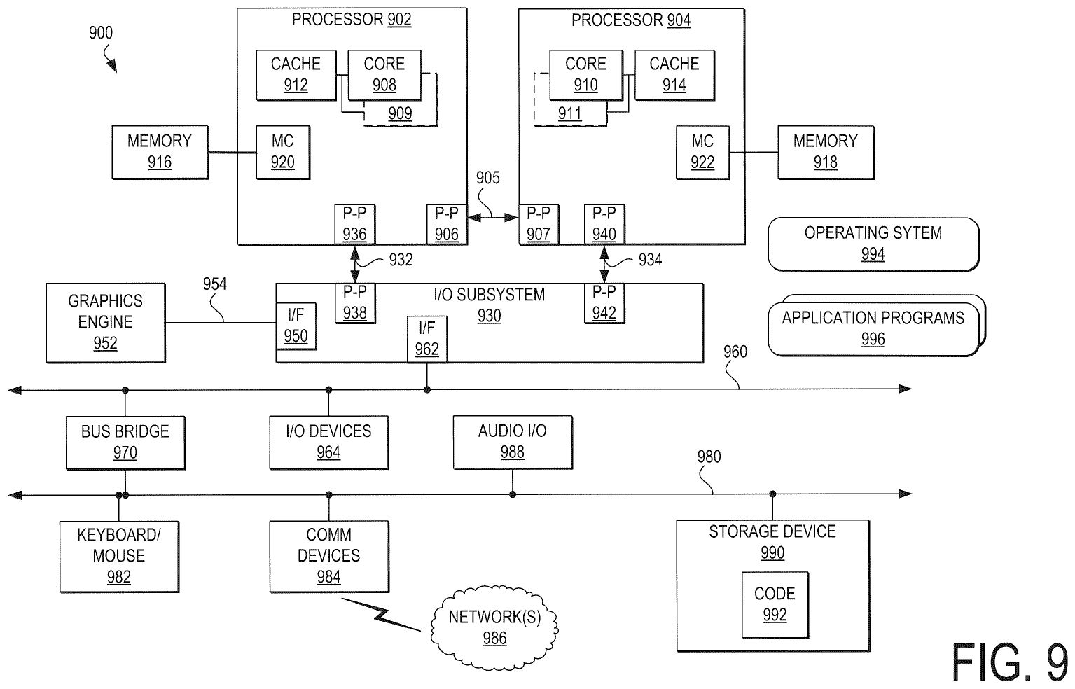

FIGS. 1A-1C illustrate perspective views of an example system 100 incorporating a thermal/EMI shielding cover of the present disclosure, and FIG. 2 illustrates a side view of the system 100. The example system 100 includes a circuit board 102, a peripheral device connector 103 coupled to the circuit board 102, and a peripheral device 104 coupled to the connector 103. The circuit board 102 may be, for example, a mother board or main board of a computer system in certain embodiments, and the peripheral device connector 103 may be configured to physically and electrically couple the device 104 to the circuit board 102. In some embodiments, the peripheral device connector 103 and/or the device 104 may conform with certain device standards or specifications, e.g., M.2 specifications (also known as next generation form factor (NGFF)). The device 104 may include a circuit board with one or more chips 108 or other circuit components thereon. For example, the device 104 may be a memory module (e.g., memory 804 of FIG. 8 or memories 916, 918 of FIG. 9), a storage module (e.g., a SSD embodied as data storage 808 of FIG. 8 or storage device 990 of FIG. 9), or another type of peripheral device (e.g., an I/O device such as 964 of FIG. 9) that couples to the circuit board 102, which may be embodied as a mother board of a computer system. In some cases, the peripheral device connector 103 may be an expansion slot of a motherboard and the device 104 may be an expansion card to be inserted into the expansion slot.

In addition, the system 100 includes a thermal/EMI shielding housing coupled to the connector 103. The housing includes a cover 106 and a attachment mechanism 105, both of which may be formed of metal in certain embodiments. The housing can be sized to substantially encompass the device 104 as shown, to allow for EMI shielding of the device 104. As used herein, the substantially encompass may refer to a first object (or multiple first objects) surrounding a large majority (e.g., greater than 60%, 75%, or 85%) of a second object. For example, the device 104 is substantially encompassed by the cover 106 and the circuit board 102 when the cover 106 is lowered into place as shown in FIG. 1C. In particular, the device 104 is effectively surrounded by the housing (which includes both the cover 106 and the mechanism 105) on at least four sides and the circuit board 102 on another. While there may be some small areas not entirely covered or sealed by the housing and the circuit board 102 when the housing is lowered, the device 104 may nonetheless be considered to be encompassed as used herein.

In addition, the cover 106 can be in contact with the device 104 to allow for thermal transfer from the device (e.g., from the chips 108). In some embodiments, one or more thermal gap pad(s) 109 may be coupled to an underside surface of the cover 106 such that the pad(s) 109 contact the chips 108 of the device 104 to allow for thermal transfer from the chips to the cover 106. In other embodiments, the pad(s) 109 may be coupled to the top surfaces of the chips 108 (and/or to other components of the device 104) to thermally couple the chips 108 to the cover 106. The thermal gap pad(s) 109 may be formed from a compressible, thermally conductive material.

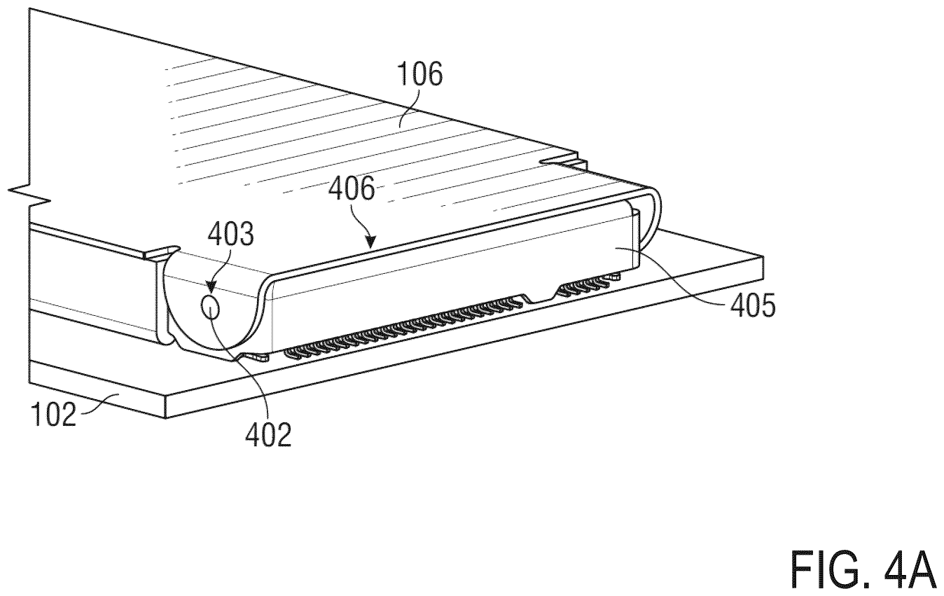

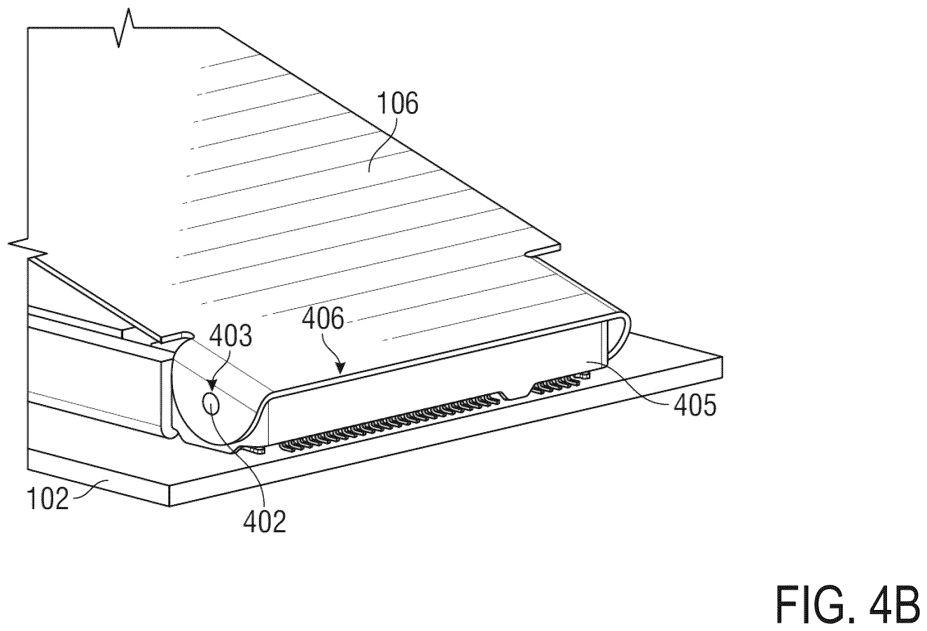

The cover 106 is sized to encompass the device 104 when the device is connected to the connector 103 and the cover 106 is in the position shown in FIG. 1C (where the device 104 is positioned such that it's circuit board is approximately parallel with the circuit board 102, as shown in FIG. 2). Although shown as having a generally rectangular shape, the cover 106 may be formed in another manner. Further, while the example shown in FIGS. 1A-1C illustrates the cover 106 as having a large top surface with side surfaces extending approximately perpendicular from the top surface, the cover 106 may be formed to have only the top surface with the side surfaces being formed separately and coupled to the circuit board (e.g., as shown in FIG. 4B).

The example attachment mechanism 105 includes a hinge 107 to allow movement of the cover 106 up and down as shown in FIGS. 1A-1C. For instance, the cover 106 can be lifted away from the circuit board 102 as shown in FIG. 1A to allow the device 104 to be inserted into the connector 103. The device 104 can then be moved down toward the circuit board 102 as shown in FIG. 1B, and in some instances, the device 104 can be secured to the circuit board at an end opposite the end coupled to the connector 103. For example, a screw or other attachment mechanism (e.g. those described further below) can be inserted into the cutout 112 and couple to the circuit board 102 via a mechanism 114 coupled to or integrated with the circuit board 102.

When lowered down toward the circuit board 102 as shown in FIG. 1C, the cover 106 encompasses at least four sides of the device 104, and the device is substantially encompassed between the cover 106 and the circuit board 102 as shown in FIG. 2. In some cases, the cover 106 may contact the circuit board 102 itself, while it might rest slightly above the circuit board in other cases (e.g., as shown in FIG. 2). The example system 100 also has a conductive gasket 110 coupled to an edge of the cover 106. In certain embodiments, the gasket 110 may be disposed around a perimeter of the cover 106, e.g., on an outer edge of the cover 106 that may come into contact with the circuit board 102. The conductive gasket 110 may be a compressible, conductive material that engages with the circuit board 102 as shown in FIG. 2 to more fully encompass the device 104 within the cover 106. The conductive gasket 110 may be soldered to the cover 106 in some embodiments, which can help to avoid the use of pressure sensitive adhesive to provide electrical connection between the gasket 110 and the cover 106.

To provide EMI shielding, the cover 106 may be connected to a ground signal of the circuit board 102. For example, in some embodiments, the attachment mechanism 105 (which may be made of a conductive material, such as metal) can be connected to a ground signal of the circuit board 102 via the connector 103, as shown in FIG. 2. The cover 106 may be electrically connected to the attachment mechanism 105 via the hinge 107, which would cause the cover 106 to also be connected to the ground signal to provide EMI shielding of the device 104. As another example, in some embodiments, the conductive gasket 110 may be in contact with a trace of the circuit board 102 that is connected to ground, when the cover 106 is lowered into place as shown in FIG. 1C. The conductive gasket 110 may be similarly electrically connected to the cover 106, and may accordingly connect the cover 106 to the ground signal.

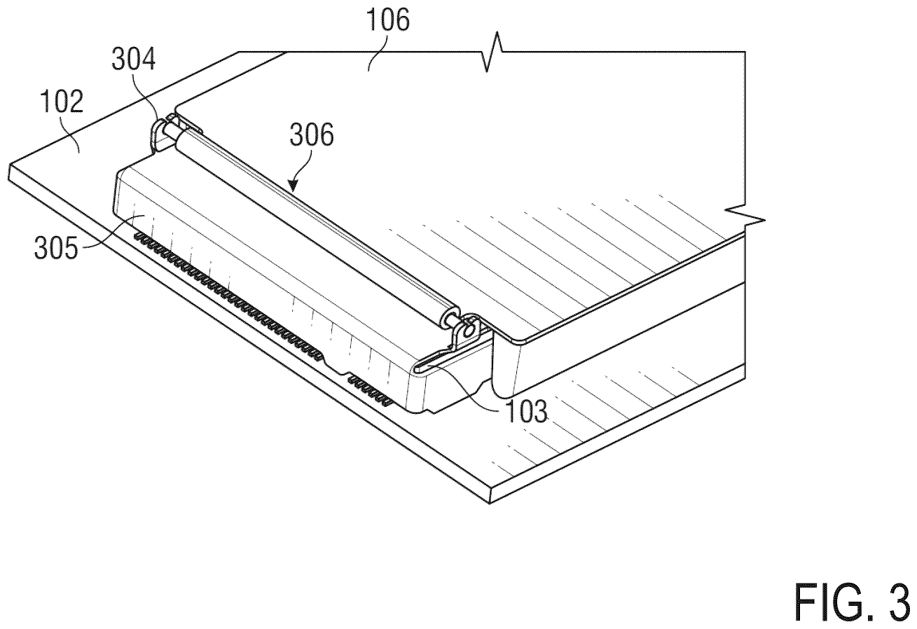

In the example shown in FIGS. 1A-1C and FIG. 2, the attachment mechanism 105 covers just a portion of the top surface of the connector 103 and includes a pin inside a generally cylindrical portion of the cover 106. However, the attachment mechanism 105 may be formed in other ways in other embodiments. FIGS. 3 and 4A-4B illustrate other example embodiments of attachment mechanisms that can be used with embodiments of the present disclosure.

Referring first to the example shown in FIG. 3, the example attachment mechanism 300 includes a connector cover 305 that encompasses approximately all of the previously exposed areas of the device connector 103 (e.g., the areas that were exposed in FIGS. 1A-1C using the mechanism 105, and/or the areas would otherwise be exposed if the cover 106 were coupled directly to the connector 103). That is, the cover 305 encompasses four sides of the connector 103, including a large portion of the top surface of the connector 103 and large portions of each of the side surfaces of the connector 103. This additional coverage of the connector 103 by the cover 305 (which may be a conductive material, such as metal, similar to the mechanism 105) can provide additional EMI shielding for the device 104 beyond that provided by the cover 106. The example cover 305 uses a similar pin-based hinge as the attachment mechanism 105 shown in FIGS. 1A-1C, and includes a pin 304 through a generally cylindrical portion 306 of the cover 106 as shown. The cover 305 can be connected to ground in the same or similar manner as the mechanism 105, e.g., via the connector 103 as previously discussed.

In some cases, the pin-based hinge shown in FIGS. 1A-1C, 2, and 3, may add too much Z-height to the overall package. In these cases, another type of attachment mechanism can be used. For example, FIGS. 4A-4B illustrate an example low Z-height attachment mechanism 400 for coupling the thermal/EMI shielding cover 106 to the device connector 103. Similar to the example shown in FIG. 3, the example attachment mechanism includes a cover 405 that encompasses at least four sides of the device connector 103, e.g., most or all of the surface area not covered by the cover 106 (whose portion 406 in the example covers the top surface of the connector 103 as well as side surfaces of the connector 103). However, rather than using a pin-based hinge like the previous examples, the example attachment mechanism of FIGS. 4A-4B includes protrusions 402 on opposite sides of the cover 405, which allow for holes 403 in an extended portion 406 of the cover 106 to engage therewith to allow the cover 106 to rotate/move about an axis running through the protrusions 402 as shown in FIGS. 4A-4B. The cover 405 can be connected to ground in the same or similar manner as the cover 305 of FIG. 3 or mechanism 105 of FIGS. 1A-1C, e.g., through a connection in the connector 103.

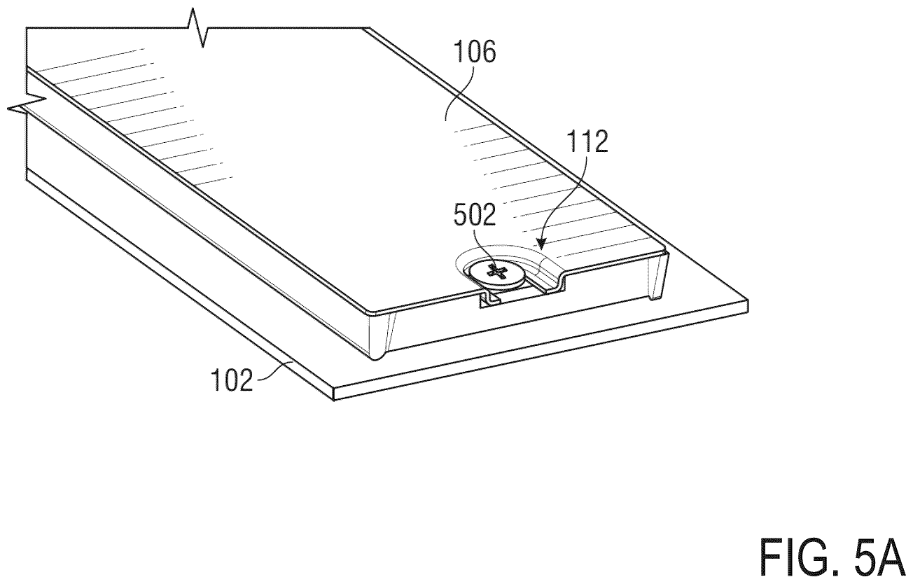

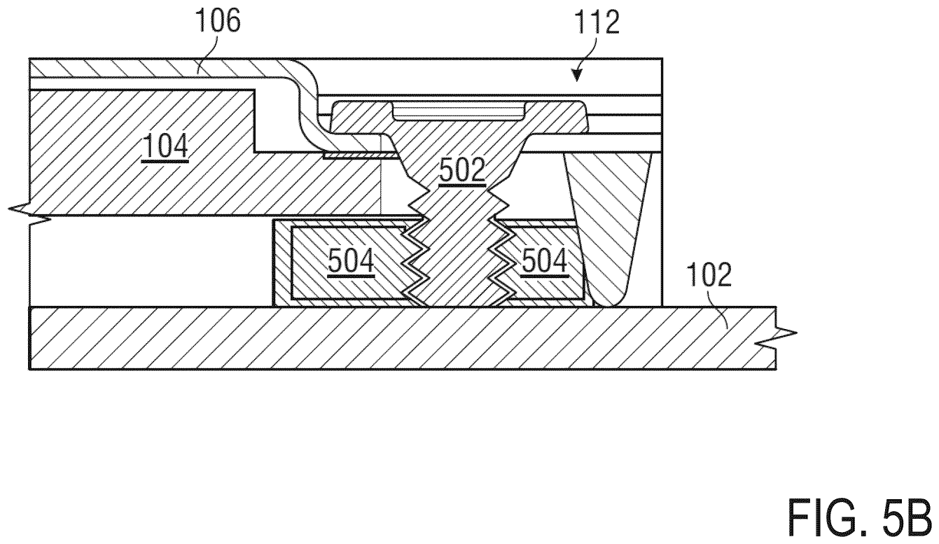

FIGS. 5A-5B illustrate an example attachment mechanism for coupling the thermal/EMI shielding cover 106 to the circuit board 102. In particular, in the example shown, the cover 106 includes a generally U-shaped cutout 112 that exposes a threaded hole 504 in or coupled to the circuit board 102, and the attachment mechanism includes a screw 502 that engages with the threaded hole in/coupled to the circuit board 102 to secure the cover 106 (and the device 104 underneath). The cutout 112 and the screw-based attachment mechanism may thus be similar to existing M.2 mechanisms for securing devices to the circuit boards to which they are connected.

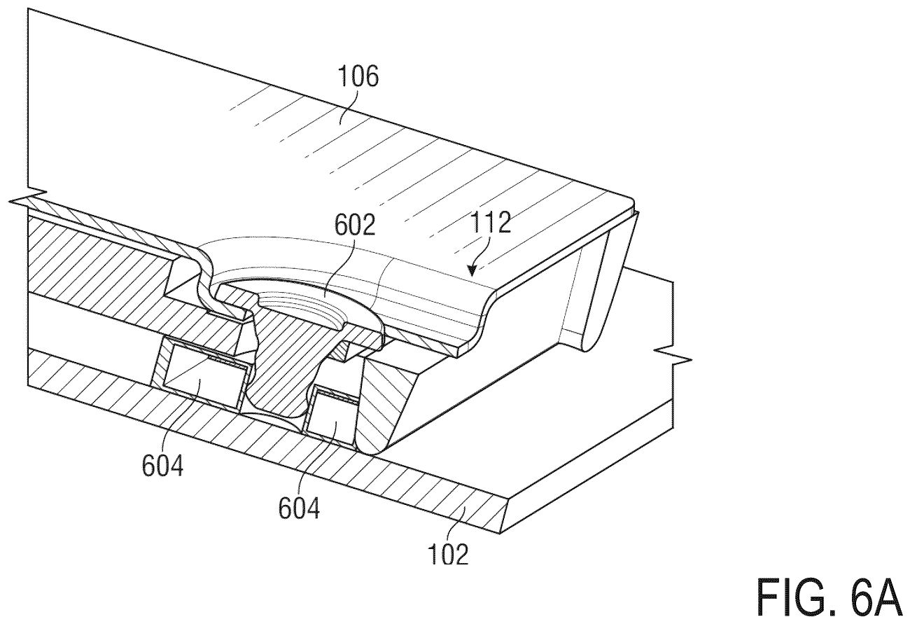

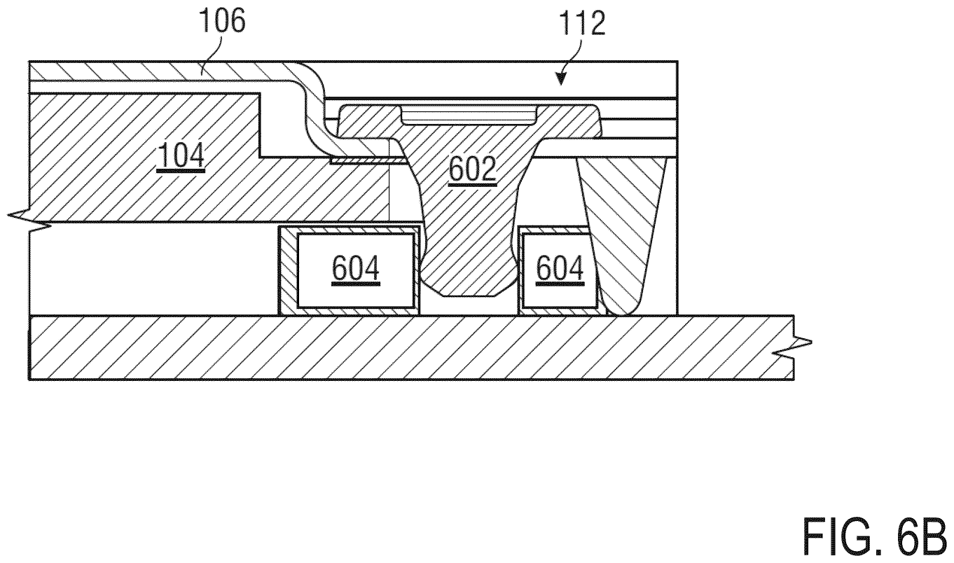

FIGS. 6A-6B illustrate another example attachment mechanism for coupling a thermal/EMI shielding cover to a circuit board. The example mechanism is similar to that shown in FIGS. 5A-5B, however, in this example, the cover 106 is secured using a button mechanism instead of a screw and threaded hole. The button mechanism includes a button 602 that is inserted into a hole 604 coupled to or integrated in the circuit board 102. The button 602 may be slightly larger in size as compared with the hole 604, but may consist of a flexible material that allows the button 602 to deform slightly when pushed into the hole 604. The inner walls of the hole 604 may be similarly flexible to allow the extended portion of the button to remain inside the hole, while the upper rim of the hole 604 may be less flexible to prevent the button 602 from receding out of the hole 604 during use. However, relatively normal force of a user may be able to remove the button 602 from the hole 604, e.g., when the user wants to raise the cover 106 to remove the device 104.

Although certain example attachment mechanisms are shown, others may be implemented as well. As an example, certain embodiments may include a push latch mechanism (e.g., a push-push latch) for securing the cover 106 to the circuit board 102.

### EXAMPLE COMPUTING SYSTEMS

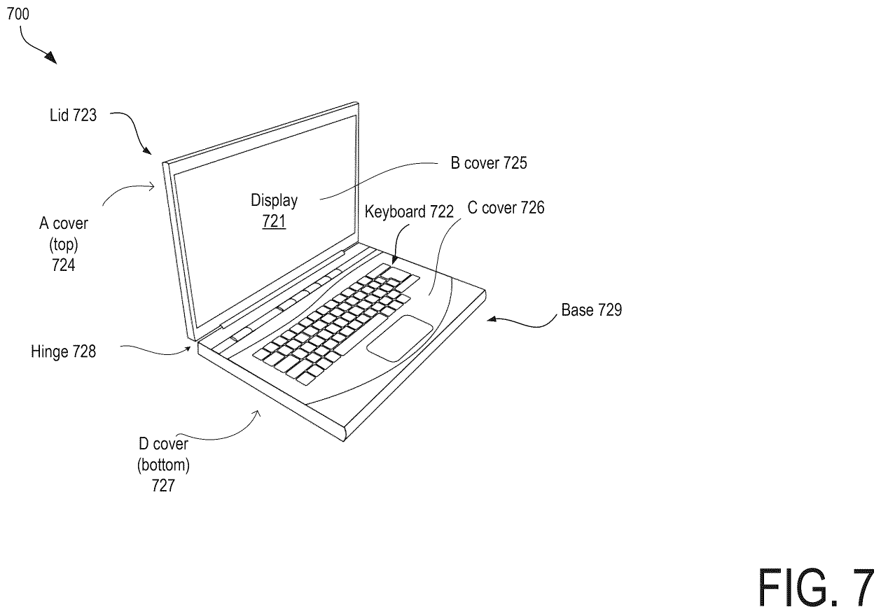

FIG. 7 illustrates an example laptop computing device 700 in which aspects of the present disclosure may be incorporated. The computing device 700 can be a laptop (as shown) or another type of mobile computing device with a similar form factor, such as a foldable tablet or smartphone. In some embodiments, embodiments of present disclosure may be incorporated into a free-standing display monitor, which may be connected to a computing device that outputs image data to the display.

The computing device 700 includes a lid 723 with an A cover 724 that is a “world-facing” surface of the lid 723 when the computing device 700 is in a closed configuration and a B cover 725 that comprises a user-facing display 721 when the lid 723 is open (e.g., as shown). The computing device 700 also includes a base 729 with a C cover 726 that includes a keyboard 722 that is upward facing when the device 700 is an open configuration (e.g., as shown) and a D cover 727 that forms the bottom of the base 729. In some embodiments, the base 729 includes the primary computing resources (e.g., host processor unit(s), graphics processing unit (GPU)) of the device 700, along with a battery, memory, and storage, and communicates with the lid 723 via wires that pass through a hinge 728 that connects the base 729 with the lid 723. In some embodiments, the computing device 700 can be a dual display device with a second display comprising a portion of the C cover 726. For example, in some embodiments, an “always-on” display (AOD) can occupy a region of the C cover below the keyboard that is visible when the lid 723 is closed. In other embodiments, a second display covers most of the surface of the C cover and a removable keyboard can be placed over the second display or the second display can present a virtual keyboard to allow for keyboard input.

FIG. 8 illustrates a simplified block diagram of a computing device in which aspects of the present disclosure may be incorporated. The computing device 800 for selective updating of a display is shown. In use, the illustrative computing device 800 determines one or more regions of a display to be updated. For example, a user may move a cursor and a clock may change from one frame to the next, requiring an update to two regions of a display. The computing device 800 sends update regions from a source to a sink in the display 818 over a link. In the illustrative embodiment, the source does not have direct access to the link port while the sink does have direct access to the link port. The source can send an indication that a particular update message is the last message to be sent for the current frame, after which the source will be entering an idle period without sending update messages. The sink can then place the link in a low-power state to reduce power usage.

The computing device 800 may be embodied as any type of computing device. For example, the computing device 800 may be embodied as or otherwise be included in, without limitation, a server computer, an embedded computing system, a System-on-a-Chip (SoC), a multiprocessor system, a processor-based system, a consumer electronic device, a smartphone, a cellular phone, a desktop computer, a tablet computer, a notebook computer, a laptop computer, a network device, a router, a switch, a networked computer, a wearable computer, a handset, a messaging device, a camera device, and/or any other computing device. In some embodiments, the computing device 800 may be located in a data center, such as an enterprise data center (e.g., a data center owned and operated by a company and typically located on company premises), managed services data center (e.g., a data center managed by a third party on behalf of a company), a co-located data center (e.g., a data center in which data center infrastructure is provided by the data center host and a company provides and manages their own data center components (servers, etc.)), cloud data center (e.g., a data center operated by a cloud services provider that host companies applications and data), and an edge data center (e.g., a data center, typically having a smaller footprint than other data center types, located close to the geographic area that it serves).

The illustrative computing device 800 includes a processor 802, a memory 804, an input/output (I/O) subsystem 806, data storage 808, a communication circuit 810, a graphics processing unit 812, a camera 814, a microphone 816, a display 818, and one or more peripheral devices 820. In some embodiments, one or more of the illustrative components of the computing device 800 may be incorporated in, or otherwise form a portion of, another component. For example, the memory 804, or portions thereof, may be incorporated in the processor 802 in some embodiments. In some embodiments, one or more of the illustrative components may be physically separated from another component.

The processor 802 may be embodied as any type of processor capable of performing the functions described herein. For example, the processor 802 may be embodied as a single or multi-core processor(s), a single or multi-socket processor, a digital signal processor, a graphics processor, a neural network compute engine, an image processor, a microcontroller, or other processor or processing/controlling circuit. Similarly, the memory 804 may be embodied as any type of volatile or non-volatile memory or data storage capable of performing the functions described herein. In operation, the memory 804 may store various data and software used during operation of the computing device 800 such as operating systems, applications, programs, libraries, and drivers. The memory 804 is communicatively coupled to the processor 802 via the I/O subsystem 806, which may be embodied as circuitry and/or components to facilitate input/output operations with the processor 802, the memory 804, and other components of the computing device 800. For example, the I/O subsystem 806 may be embodied as, or otherwise include, memory controller hubs, input/output control hubs, firmware devices, communication links (i.e., point-to-point links, bus links, wires, cables, light guides, printed circuit board traces, etc.) and/or other components and subsystems to facilitate the input/output operations. The I/O subsystem 806 may connect various internal and external components of the computing device 800 to each other with use of any suitable connector, interconnect, bus, protocol, etc., such as an SoC fabric, PCIe®, USB2, USB3, USB4, NVMe®, Thunderbolt®, and/or the like. In some embodiments, the I/O subsystem 806 may form a portion of a system-on-a-chip (SoC) and be incorporated, along with the processor 802, the memory 804, and other components of the computing device 800 on a single integrated circuit chip.

The data storage 808 may be embodied as any type of device or devices configured for the short-term or long-term storage of data. For example, the data storage 808 may include any one or more memory devices and circuits, memory cards, hard disk drives, solid-state drives, or other data storage devices.

The communication circuit 810 may be embodied as any type of interface capable of interfacing the computing device 800 with other computing devices, such as over one or more wired or wireless connections. In some embodiments, the communication circuit 810 may be capable of interfacing with any appropriate cable type, such as an electrical cable or an optical cable. The communication circuit 810 may be configured to use any one or more communication technology and associated protocols (e.g., Ethernet, Bluetooth®, Wi-Fi®, WiMAX, near field communication (NFC), etc.). The communication circuit 810 may be located on silicon separate from the processor 802, or the communication circuit 810 may be included in a multi-chip package with the processor 802, or even on the same die as the processor 802. The communication circuit 810 may be embodied as one or more add-in-boards, daughtercards, network interface cards, controller chips, chipsets, specialized components such as a field-programmable gate array (FPGA) or application-specific integrated circuit (ASIC), or other devices that may be used by the computing device 800 to connect with another computing device. In some embodiments, communication circuit 810 may be embodied as part of a system-on-a-chip (SoC) that includes one or more processors or included on a multichip package that also contains one or more processors. In some embodiments, the communication circuit 810 may include a local processor (not shown) and/or a local memory (not shown) that are both local to the communication circuit 810. In such embodiments, the local processor of the communication circuit 810 may be capable of performing one or more of the functions of the processor 802 described herein. Additionally or alternatively, in such embodiments, the local memory of the communication circuit 810 may be integrated into one or more components of the computing device 800 at the board level, socket level, chip level, and/or other levels.

The graphics processing unit 812 is configured to perform certain computing tasks, such as video or graphics processing. The graphics processing unit 812 may be embodied as one or more processors, data processing unit, field-programmable gate arrays (FPGAs), application-specific integrated circuits (ASICs), and/or any combination of the above. In some embodiments, the graphics processing unit 812 may send frames or partial update regions to the display 818. For instance, the example graphics processing unit 812 includes a display engine 813, which may be embodied as hardware, firmware, software, virtualized hardware, emulated architecture, and/or a combination thereof, and is configured to determine frames to be sent to the display 818 and send the images to the display 818. In the illustrative embodiment, the display engine 813 is part of the graphics processing unit 812. In other embodiments, the display engine 813 may be part of the processor 802 or other component of the device 800.

The camera 814 may include one or more fixed or adjustable lenses and one or more image sensors. The image sensors may be any suitable type of image sensors, such as a CMOS or CCD image sensor. The camera 814 may have any suitable aperture, focal length, field of view, etc. For example, the camera 814 may have a field of view of 60-110° in the azimuthal and/or elevation directions.

The microphone 816 is configured to sense sound waves and output an electrical signal indicative of the sound waves. In the illustrative embodiment, the computing device 800 may have more than one microphone 816, such as an array of microphones 816 in different positions.

The display 818 may be embodied as any type of display on which information may be displayed to a user of the computing device 800, such as a touchscreen display, a liquid crystal display (LCD), a thin film transistor LCD (TFT-LCD), a light-emitting diode (LED) display, an organic light-emitting diode (OLED) display, a cathode ray tube (CRT) display, a plasma display, an image projector (e.g., 2D or 3D), a laser projector, a heads-up display, and/or other display technology. The display 818 may have any suitable resolution, such as 7680×4320, 3840×2160, 1920×1200, 1920×1080, etc.

The display 818 includes a timing controller (TCON) 819, which includes circuitry to convert video data received from the graphics processing unit 812 into signals that drive a panel of the display 818. In some embodiments, the TCON 819 may also include circuitry to implement one or more aspects of the present disclosure. For example, the TCON 819 may enhance frames received from the graphics processing unit 812 and stream the frames to the panel of the display 818.

In some embodiments, the computing device 800 may include other or additional components, such as those commonly found in a computing device. For example, the computing device 800 may also have peripheral devices 820, such as a keyboard, a mouse, a speaker, an external storage device, etc. In some embodiments, the computing device 800 may be connected to a dock that can interface with various devices, including peripheral devices 820. In some embodiments, the peripheral devices 820 may include additional sensors that the computing device 800 can use to monitor the video conference, such as a time-of-flight sensor or a millimeter-wave sensor.

FIG. 9 is a block diagram of computing device components which may be included in a mobile computing device incorporating aspects of the present disclosure. Generally, components shown in FIG. 9 can communicate with other shown components, although not all connections are shown, for ease of illustration. The components 900 comprise a multiprocessor system comprising a first processor 902 and a second processor 904 and is illustrated as comprising point-to-point (P-P) interconnects. For example, a point-to-point (P-P) interface 906 of the processor 902 is coupled to a point-to-point interface 907 of the processor 904 via a point-to-point interconnection 905. It is to be understood that any or all of the point-to-point interconnects illustrated in FIG. 9 can be alternatively implemented as a multi-drop bus, and that any or all buses illustrated in FIG. 9 could be replaced by point-to-point interconnects.

As shown in FIG. 9, the processors 902 and 904 are multicore processors. Processor 902 comprises processor cores 908 and 909, and processor 904 comprises processor cores 910 and 911. Processor cores 908-911 can execute computer-executable instructions in a manner similar to that discussed below, or in other manners.

Processors 902 and 904 further comprise at least one shared cache 912 and 914, respectively. The shared caches 912 and 914 can store data (e.g., instructions) utilized by one or more components of the processor, such as the processor cores 908-909 and 910-911. The shared caches 912 and 914 can be part of a memory hierarchy for the device. For example, the shared cache 912 can locally store data that is also stored in a memory 916 to allow for faster access to the data by components of the processor 902. In some embodiments, the shared caches 912 and 914 can comprise multiple cache layers, such as level 1 (L1), level 2 (L2), level 3 (L3), level 4 (L4), and/or other caches or cache layers, such as a last level cache (LLC).

Although two processors are shown, the device can comprise any number of processors or other compute resources. Further, a processor can comprise any number of processor cores. A processor can take various forms such as a central processing unit, a controller, a graphics processor, an accelerator (such as a graphics accelerator, digital signal processor (DSP), or artificial intelligence (AI) accelerator)). A processor in a device can be the same as or different from other processors in the device. In some embodiments, the device can comprise one or more processors that are heterogeneous or asymmetric to a first processor, accelerator, field programmable gate array (FPGA), or any other processor. There can be a variety of differences between the processing elements in a system in terms of a spectrum of metrics of merit including architectural, microarchitectural, thermal, power consumption characteristics and the like. These differences can effectively manifest themselves as asymmetry and heterogeneity amongst the processors in a system. In some embodiments, the processors 902 and 904 reside in a multi-chip package. As used herein, the terms “processor unit” and “processing unit” can refer to any processor, processor core, component, module, engine, circuitry or any other processing element described herein. A processor unit or processing unit can be implemented in hardware, software, firmware, or any combination thereof capable of.

Processors 902 and 904 further comprise memory controller logic (MC) 920 and 922. As shown in FIG. 9, MCs 920 and 922 control memories 916 and 918 coupled to the processors 902 and 904, respectively. The memories 916 and 918 can comprise various types of memories, such as volatile memory (e.g., dynamic random-access memories (DRAM), static random-access memory (SRAM)) or non-volatile memory (e.g., flash memory, solid-state drives, chalcogenide-based phase-change non-volatile memories). While MCs 920 and 922 are illustrated as being integrated into the processors 902 and 904, in alternative embodiments, the MCs can be logic external to a processor, and can comprise one or more layers of a memory hierarchy.

Processors 902 and 904 are coupled to an Input/Output (I/O) subsystem 930 via P-P interconnections 932 and 934. The point-to-point interconnection 932 connects a point-to-point interface 936 of the processor 902 with a point-to-point interface 938 of the I/O subsystem 930, and the point-to-point interconnection 934 connects a point-to-point interface 940 of the processor 904 with a point-to-point interface 942 of the I/O subsystem 930.

Input/Output subsystem 930 further includes an interface 950 to couple I/O subsystem 930 to a graphics module 952, which can be a high-performance graphics module. The I/O subsystem 930 and the graphics module 952 are coupled via a bus 954. Alternately, the bus 954 could be a point-to-point interconnection.

Input/Output subsystem 930 is further coupled to a first bus 960 via an interface 962. The first bus 960 can be a Peripheral Component Interconnect (PCI) bus, a PCI Express (PCIe) bus, another third generation I/O (input/output) interconnection bus or any other type of bus.

Various I/O devices 964 can be coupled to the first bus 960. A bus bridge 970 can couple the first bus 960 to a second bus 980. In some embodiments, the second bus 980 can be a low pin count (LPC) bus. Various devices can be coupled to the second bus 980 including, for example, a keyboard/mouse 982, audio I/O devices 988 and a storage device 990, such as a hard disk drive, solid-state drive or other storage device for storing computer-executable instructions (code) 992. The code 992 can comprise computer-executable instructions for performing technologies described herein. Additional components that can be coupled to the second bus 980 include communication device(s) or components 984, which can provide for communication between the device and one or more wired or wireless networks 986 (e.g. Wi-Fi, cellular or satellite networks) via one or more wired or wireless communication links (e.g., wire, cable, Ethernet connection, radio-frequency (RF) channel, infrared channel, Wi-Fi channel) using one or more communication standards (e.g., IEEE 802.11 standard and its supplements).

The device can comprise removable memory such as flash memory cards (e.g., SD (Secure Digital) cards), memory sticks, Subscriber Identity Module (SIM) cards). The memory in the computing device (including caches 912 and 914, memories 916 and 918 and storage device 990) can store data and/or computer-executable instructions for executing an operating system 994, or application programs 996. Example data includes web pages, text messages, images, sound files, video data, sensor data, or other data sets to be sent to and/or received from one or more network servers or other devices by the device via one or more wired or wireless networks, or for use by the device. The device can also have access to external memory (not shown) such as external hard drives or cloud-based storage.

The operating system 994 can control the allocation and usage of the components illustrated in FIG. 9 and support one or more application programs 996. The application programs 996 can include common mobile computing device applications (e.g., email applications, calendars, contact managers, web browsers, messaging applications) as well as other computing applications.

The device can support various input devices, such as a touchscreen, microphones, cameras (monoscopic or stereoscopic), trackball, touchpad, trackpad, mouse, keyboard, proximity sensor, light sensor, pressure sensor, infrared sensor, electrocardiogram (ECG) sensor, PPG (photoplethysmogram) sensor, galvanic skin response sensor, and one or more output devices, such as one or more speakers or displays. Any of the input or output devices can be internal to, external to or removably attachable with the device. External input and output devices can communicate with the device via wired or wireless connections.

In addition, the computing device can provide one or more natural user interfaces (NUIs). For example, the operating system 994 or application programs 996 can comprise speech recognition as part of a voice user interface that allows a user to operate the device via voice commands. Further, the device can comprise input devices and components that allows a user to interact with the device via body, hand, or face gestures.

The device can further comprise one or more communication components 984. The components 984 can comprise wireless communication components coupled to one or more antennas to support communication between the device and external devices. Antennas can be located in a base, lid, or other portion of the device. The wireless communication components can support various wireless communication protocols and technologies such as Near Field Communication (NFC), IEEE 1002.11 (Wi-Fi) variants, WiMax, Bluetooth, Zigbee, 4G Long Term Evolution (LTE), Code Division Multiplexing Access (CDMA), Universal Mobile Telecommunication System (UMTS) and Global System for Mobile Telecommunication (GSM). In addition, the wireless modems can support communication with one or more cellular networks for data and voice communications within a single cellular network, between cellular networks, or between the mobile computing device and a public switched telephone network (PSTN).

The device can further include at least one input/output port (which can be, for example, a USB, IEEE 1394 (FireWire), Ethernet and/or RS-232 port) comprising physical connectors; a power supply (such as a rechargeable battery); a satellite navigation system receiver, such as a GPS receiver; a gyroscope; an accelerometer; and a compass. A GPS receiver can be coupled to a GPS antenna. The device can further include one or more additional antennas coupled to one or more additional receivers, transmitters and/or transceivers to enable additional functions.

FIG. 9 illustrates one example computing device architecture. Computing devices based on alternative architectures can be used to implement technologies described herein. For example, instead of the processors 902 and 904, and the graphics module 952 being located on discrete integrated circuits, a computing device can comprise a SoC (system-on-a-chip) integrated circuit incorporating one or more of the components illustrated in FIG. 9. In one example, an SoC can comprise multiple processor cores, cache memory, a display driver, a GPU, multiple I/O controllers, an AI accelerator, an image processing unit driver, I/O controllers, an AI accelerator, an image processor unit. Further, a computing device can connect elements via bus or point-to-point configurations different from that shown in FIG. 9. Moreover, the illustrated components in FIG. 9 are not required or all-inclusive, as shown components can be removed and other components added in alternative embodiments.

As used in any embodiment herein, the term “module” refers to logic that may be implemented in a hardware component or device, software or firmware running on a processor, or a combination thereof, to perform one or more operations consistent with the present disclosure. Software may be embodied as a software package, code, instructions, instruction sets and/or data recorded on non-transitory computer-readable storage mediums. Firmware may be embodied as code, instructions or instruction sets and/or data that are hard-coded (e.g., nonvolatile) in memory devices. As used in any embodiment herein, the term “circuitry” can comprise, for example, singly or in any combination, hardwired circuitry, programmable circuitry such as computer processors comprising one or more individual instruction processing cores, state machine circuitry, and/or firmware that stores instructions executed by programmable circuitry. Modules described herein may, collectively or individually, be embodied as circuitry that forms a part of one or more devices. Thus, any of the modules can be implemented as circuitry, such as continuous itemset generation circuitry, entropy-based discretization circuitry, etc. A computer device referred to as being programmed to perform a method can be programmed to perform the method via software, hardware, firmware or combinations thereof.

The use of reference numbers in the claims and the specification is meant as in aid in understanding the claims and the specification and is not meant to be limiting.

Any of the disclosed methods can be implemented as computer-executable instructions or a computer program product. Such instructions can cause a computer or one or more processors capable of executing computer-executable instructions to perform any of the disclosed methods. Generally, as used herein, the term “computer” refers to any computing device or system described or mentioned herein, or any other computing device. Thus, the term “computer-executable instruction” refers to instructions that can be executed by any computing device described or mentioned herein, or any other computing device.

The computer-executable instructions or computer program products as well as any data created and used during implementation of the disclosed technologies can be stored on one or more tangible or non-transitory computer-readable storage media, such as optical media discs (e.g., DVDs, CDs), volatile memory components (e.g., DRAM, SRAM), or non-volatile memory components (e.g., flash memory, solid state drives, chalcogenide-based phase-change non-volatile memories). Computer-readable storage media can be contained in computer-readable storage devices such as solid-state drives, USB flash drives, and memory modules. Alternatively, the computer-executable instructions may be performed by specific hardware components that contain hardwired logic for performing all or a portion of disclosed methods, or by any combination of computer-readable storage media and hardware components.

The computer-executable instructions can be part of, for example, a dedicated software application or a software application that is accessed via a web browser or other software application (such as a remote computing application). Such software can be read and executed by, for example, a single computing device or in a network environment using one or more networked computers. Further, it is to be understood that the disclosed technology is not limited to any specific computer language or program. For instance, the disclosed technologies can be implemented by software written in C++, Java, Perl, Python, JavaScript, Adobe Flash, or any other suitable programming language. Likewise, the disclosed technologies are not limited to any particular computer or type of hardware.

Furthermore, any of the software-based embodiments (comprising, for example, computer-executable instructions for causing a computer to perform any of the disclosed methods) can be uploaded, downloaded or remotely accessed through a suitable communication means. Such suitable communication means include, for example, the Internet, the World Wide Web, an intranet, cable (including fiber optic cable), magnetic communications, electromagnetic communications (including RF, microwave, and infrared communications), electronic communications, or other such communication means.

As used in this application and in the claims, a list of items joined by the term “and/or” can mean any combination of the listed items. For example, the phrase “A, B and/or C” can mean A; B; C; A and B; A and C; B and C; or A, B, and C. Further, as used in this application and in the claims, a list of items joined by the term “at least one of” can mean any combination of the listed terms. For example, the phrase “at least one of A, B, or C” can mean A; B; C; A and B; A and C; B and C; or A, B, and C. Moreover, as used in this application and in the claims, a list of items joined by the term “one or more of” can mean any combination of the listed terms. For example, the phrase “one or more of A, B and C” can mean A; B; C; A and B; A and C; B and C; or A, B, and C.

The disclosed methods, apparatuses and systems are not to be construed as limiting in any way. Instead, the present disclosure is directed toward all novel and nonobvious features and aspects of the various disclosed embodiments, alone and in various combinations and subcombinations with one another. The disclosed methods, apparatuses, and systems are not limited to any specific aspect or feature or combination thereof, nor do the disclosed embodiments require that any one or more specific advantages be present or problems be solved.

Although the operations of some of the disclosed methods are described in a particular, sequential order for convenient presentation, it is to be understood that this manner of description encompasses rearrangement, unless a particular ordering is required by specific language set forth herein. For example, operations described sequentially may in some cases be rearranged or performed concurrently. Moreover, for the sake of simplicity, the attached figures may not show the various ways in which the disclosed methods can be used in conjunction with other methods.

Certain non-limiting examples of the presently described techniques are provided below. Each of the following non-limiting examples may stand on its own or may be combined in any permutation or combination with any one or more of the other examples provided below or throughout the present disclosure.

Example 1 is an apparatus comprising: a circuit board; a device connector coupled to the circuit board, the device connector comprising a port to receive a peripheral device; and a housing coupled to the device connector, the housing comprising a conductive material and sized to encompass at least four sides of a peripheral device when the peripheral device is coupled to the device connector.

Example 2 includes the apparatus of Example 1, further comprising an attachment mechanism coupled to the device connector, wherein the housing is coupled to device connector via the attachment mechanism.

Example 3 includes the apparatus of Example 2, wherein the housing and the attachment mechanism are coupled via a pin-based hinge mechanism.

Example 4 includes the apparatus of Example 2, wherein the attachment mechanism comprises protrusions in respective holes of the housing.

Example 5 includes the apparatus of any one of Examples 2-4, wherein the attachment mechanism encompasses at least a majority (e.g., greater than 60%, 75% or 85%) of the device connector.

Example 6 includes the apparatus of any one of Examples 1-5, further comprising a conductive gasket coupled to the housing.

Example 7 includes the apparatus of Example 6, wherein the conductive gasket is disposed on at least a portion of an outer edge the housing and extends past a lower surface of the housing.

Example 8 includes the apparatus of any one of Examples 1-7, wherein the device connector is an M.2-compatible connector.

Example 9 includes the apparatus of any one of Examples 1-8, further comprising a processor coupled to the circuit board and a peripheral device coupled to the device connector, wherein the peripheral device is electrically coupled to the processor and the device is encompassed by the housing and the circuit board.

Example 10 includes the apparatus of any one of Examples 1-9, further comprising thermal gap pads coupled to an underside surface of the housing.

Example 11 includes the apparatus of any one of Examples 1-10, further comprising a power supply, wherein the housing is coupled to a ground signal of the power supply.

Example 12 is an apparatus comprising: a circuit board; an expansion slot coupled to the circuit board; an expansion card coupled to the expansion slot; an attachment mechanism coupled to the expansion slot; and a conductive housing coupled to the attachment mechanism via a hinge, wherein the housing is thermally coupled to the expansion card; wherein the expansion card is substantially encompassed by the conductive housing and the circuit board.

Example 13 includes the apparatus of Example 12, wherein the hinge is a pin-based hinge.

Example 14 includes the apparatus of Example 12, wherein the hinge comprises protrusions of the attachment mechanism inside holes of the housing.

Example 15 includes the apparatus of any one of Examples 12-14, further comprising a conductive gasket coupled to the housing, the gasket disposed at least partially between the housing and the circuit board.

Example 16 includes the apparatus of any one of Examples 12-15, and the housing substantially encompasses at least four sides of the expansion card.

Example 17 includes the apparatus of any one of Examples 12-16, wherein the attachment mechanism substantially encompasses at least four sides of the expansion slot.

Example 18 includes the apparatus of any one of Examples 12-17, wherein the expansion slot and expansion card are M.2-compatible.

Example 19 includes the apparatus of any one of Examples 12-18, further comprising a power supply, wherein the housing is coupled to a ground signal of the power supply.

Example 20 includes the apparatus of any one of Examples 12-19, further comprising a processor coupled to the circuit board.

Example 21 is a computing device comprising: a motherboard; a socket coupled to the motherboard, the socket to receive a peripheral device; a metal housing coupled to the socket; a peripheral device coupled to the socket, wherein the peripheral device is thermally coupled to the housing and between the housing and the motherboard.

Example 22 includes the computing device Example 21, wherein the peripheral device is substantially encompassed by the housing and the motherboard.

Example 23 includes the computing device of Example 21 or 22, wherein the metal housing is a first metal housing and the computing device further comprises a second metal housing coupled to and encompassing at least four sides of the socket (e.g., greater than 75% of the socket), wherein the first metal housing is coupled to the second metal housing via a hinge.

Example 24 includes the computing device of Example 23, wherein the peripheral device is substantially encompassed (e.g., at least 75% or at least 85%) by the first metal housing, the second metal housing, and the motherboard.

Example 25 includes the computing device of any one of Examples 21-24, further comprising a power supply, wherein the housing is coupled to a ground signal of the power supply.

Example 26 includes the computing device of any one of Examples 21-25, wherein the socket and the peripheral device are M.2-compabitble.

Example 27 includes the computing device of any one of Examples 21-26, wherein the computer device is a laptop computing device.

Example 28 includes the computing device of any one of Examples 21-26, wherein the peripheral device is at least 75% encompassed by the metal housing and the motherboard.

Example 29 includes the apparatus of any one of Examples 1-20, wherein the apparatus is a computing system, e.g., a laptop computing system.

1. An apparatus comprising:
a circuit board;
a device connector coupled to the circuit board, the device connector comprising a port to receive a peripheral device; and
a housing coupled to the device connector, the housing comprising a conductive material and sized to encompass at least four sides of a peripheral device when the peripheral device is coupled to the device connector.

2. The apparatus of claim 1, further comprising an attachment mechanism coupled to the device connector, wherein the housing is coupled to device connector via the attachment mechanism.

3. The apparatus of claim 2, wherein the housing and the attachment mechanism are coupled via a pin-based hinge mechanism.

4. The apparatus of claim 2, wherein the attachment mechanism comprises protrusions in respective holes of the housing.

5. The apparatus of claim 2, wherein the attachment mechanism encompasses at least four sides of the device connector.

6. The apparatus of claim 1, further comprising a conductive gasket coupled to the housing.

7. The apparatus of claim 1, wherein the device connector is an M.2-compatible connector.

8. The apparatus of claim 1, further comprising a processor coupled to the circuit board and a peripheral device coupled to the device connector, wherein the peripheral device is electrically coupled to the processor and the device is encompassed by the housing and the circuit board.

9. The apparatus of claim 1, further comprising thermal gap pads coupled to an underside surface of the housing.

10. An apparatus comprising:
a circuit board;
an expansion slot coupled to the circuit board;
an expansion card coupled to the expansion slot;
an attachment mechanism coupled to the expansion slot; and
a conductive housing coupled to the attachment mechanism via a hinge, wherein the housing is thermally coupled to the expansion card;
wherein the expansion card is substantially encompassed by the conductive housing and the circuit board.

11. The apparatus of claim 10, wherein the hinge is a pin-based hinge.

12. The apparatus of claim 10, wherein the hinge comprises protrusions of the attachment mechanism inside holes of the housing.

13. The apparatus of claim 10, wherein the conductive housing encompasses at least four sides of the expansion card.

14. The apparatus of claim 10, wherein the expansion card is at least 75% encompassed by the conductive housing and the circuit board.

15. The apparatus of claim 10, wherein the attachment mechanism encompasses at least four sides of the expansion slot.

16. The apparatus of claim 10, wherein the expansion card is at least 85% encompassed by the conductive housing, the attachment mechanism, and the circuit board.

17. The apparatus of claim 10, further comprising a conductive gasket coupled to the housing, the gasket disposed at least partially between the housing and the circuit board.

18. A computing device comprising:
a motherboard;
a socket coupled to the motherboard, the socket to receive a peripheral device;
a metal housing coupled to the socket;
a peripheral device coupled to the socket, wherein the peripheral device is thermally coupled to the housing and between the housing and the motherboard.

19. The computing device of claim 18, wherein the metal housing is a first metal housing and the computing device further comprises a second metal housing coupled to and encompassing at least four sides of the socket, wherein the first metal housing is coupled to the second metal housing via a hinge.

20. The computing device of claim 18, further comprising a power supply, wherein the housing is coupled to a ground signal of the power supply.
